(19) United States
(12) Patent Application Publication
(10) Pub. No.: US 2020/0048764 A1
(43) Pub. Date: Feb. 13, 2020

(54) Film Forming Apparatus and Film Forming Method

(71) Applicant: TOKYO ELECTRON LIMITED, Tokyo (JP)

(72) Inventors: Hirotaka KUWADA, Nirasaki City (JP); Yuki KEIMOTO, Nirasaki City (JP); Yu NUNOSHIGE, Nirasaki City (JP); Yasushi FUJII, Nirasaki City (JP)

(21) Appl. No.: 16/530,259

(22) Filed: Aug. 2, 2019

(30) Foreign Application Priority Data
Aug. 10, 2018 (JP) 2018-151892

(51) Int. Cl. C23C 16/458; C23C 16/52; H01L 21/02; H01L 21/687

(52) U.S. Cl. CPC C23C 16/4585; H01L 21/68735; H01L 21/0262; C23C 16/52

(57) ABSTRACT

A film forming apparatus, which forms a film on a substrate mounted on a stage in a process chamber by supplying a film forming gas to the substrate from a film forming gas supply facing the stage, includes: a first annular body surrounding the stage with a gap interposed between the stage and the first annular body; a second annular body extending downward from an inner peripheral portion of the first annular body; and a third annular body extending from a peripheral portion of the stage such that the third annular body has a flow path defining surface extending along an inner peripheral surface of the second annular body and a lower end surface of the second annular body.

### CROSS-REFERENCE TO RELATED APPLICATION

This application is based upon and claims the benefit of priority from Japanese Patent Application No. 2018-151892, filed on Aug. 10, 2018, the entire contents of which are incorporated herein by reference.

### TECHNICAL FIELD

The present disclosure relates to a field of technique for forming a film on a substrate.

### BACKGROUND

As a film forming apparatus for forming a film on a semiconductor wafer (hereinafter referred to as a “wafer”) which is a substrate, there is used a film forming apparatus including a stage for mounting the wafer in a process container under a vacuum atmosphere, and a processing gas supply facing the stage. In such a film forming apparatus, a source gas and a reaction gas reacting with the source gas are sequentially supplied to the wafer and molecular layers of a reaction product are deposited on the surface of the wafer. Thus, a thin film is obtained.

Patent Document 1 discloses a film forming apparatus for forming a film by supplying a gas toward a substrate placed on a susceptor, in which the edge of the susceptor and the edge of a ring surrounding the susceptor form a complementary stepped shape such that a minute gap bent like a hook is obtained between the ring and the susceptor. With this film forming apparatus, the adhesion amount of deposited layers in the minute gap is increased by a turbulent flow generated while the gas passes through the minute gap. Thus, entrance of a source gas to a lower space is trapped.

Patent Document 2 discloses a film forming apparatus for forming a film by supplying a reaction gas to a substrate in a process container. The film forming apparatus includes a stage configured to move upward and downward between a processing position and a substrate delivery position, and a surrounding member that surrounds the stage in the processing position so as to partition the process container into a process space and a space below the stage. The film forming apparatus further includes a clamp ring. When the stage moves upward to the processing position, the inner edge of the clamp ring is brought into contact with the peripheral edge of the substrate on the stage so that the clamp ring is lifted from the upper surface of the surrounding member. Thus, a wraparound of the reaction gas to the rear surface of the substrate is prevented. The clamp ring has a cylindrical wall which suppresses ingress of the reaction gas from a gap between the clamp ring and the surrounding member.

### PRIOR ART DOCUMENTS

### Patent Documents

Patent Document 1: Japanese laid-open publication No. 2000-12470

Patent Document 2: Japanese laid-open publication No. 2014-98202

### SUMMARY

An aspect of the present disclosure provides a film forming apparatus including: a vacuum container defining a process chamber kept in a vacuum atmosphere; a stage having an upper surface on which a substrate is mounted and a lower surface supported in the process chamber by a support, a central portion of the lower surface being supported by the support, a peripheral portion of the lower surface being spaced apart from a bottom portion of the vacuum container; a film forming gas supply installed above the stage to face the stage, and configured to supply a film forming gas to the substrate; an exhaust port opened in a side wall of the vacuum container along an outer periphery of the stage; a first annular body protruding toward the stage from the side wall of the vacuum container at a location below the exhaust port, an inner peripheral portion of the first annular body facing a circumferential surface of the stage with a gap interposed between the inner peripheral portion and the circumferential surface, the first annular body vertically partitioning the process chamber; a second annular body extending downward from the inner peripheral portion of the first annular body such that a lower end portion of the second annular body is positioned lower than the peripheral portion of the stage; and a third annular body extending from the peripheral portion of the stage, such that the third annular body has a flow path defining surface extending along an inner peripheral surface of the second annular body and a lower end surface of the second annular body and a bent flow path, in which the film forming gas leaking into the gap is trapped and forms a film on the flow path defining surface and the second annular body, is formed between the second annular body and the third annular body.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal sectional side view of a film forming apparatus according to an embodiment.

FIG. 2 is a partial transversal sectional plan view of the film forming apparatus.

FIG. 3 is an exploded perspective view of an annular plate, a cylindrical member, and a guide member provided in the film forming apparatus.

FIG. 4 is a longitudinal sectional view showing a bent flow path.

FIG. 5 is an explanatory view showing operation of the film forming apparatus.

FIG. 6 is an explanatory view showing operation of the film forming apparatus.

FIG. 7 is an explanatory view showing operation of the film forming apparatus.

FIG. 8 is an explanatory view for explaining trapping of a film forming gas in the bent flow path.

FIG. 9 is an explanatory view showing cleaning of the film forming apparatus.

FIG. 10 is an explanatory view showing cleaning of the film forming apparatus.

FIG. 11 is an explanatory view for explaining removal of a reaction product attached to the bent flow path.

FIG. 12 is an explanatory view showing another example of the bent flow path.

FIG. 13 is an explanatory view showing another example of the bent flow path.

FIG. 14 is an explanatory view showing another example of the bent flow path.

FIG. 15 is a characteristic diagram showing film thicknesses with respect to the number of processed wafers in an example.

FIG. 16 is a characteristic diagram showing film thicknesses with respect to the number of processed wafers in a comparative example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

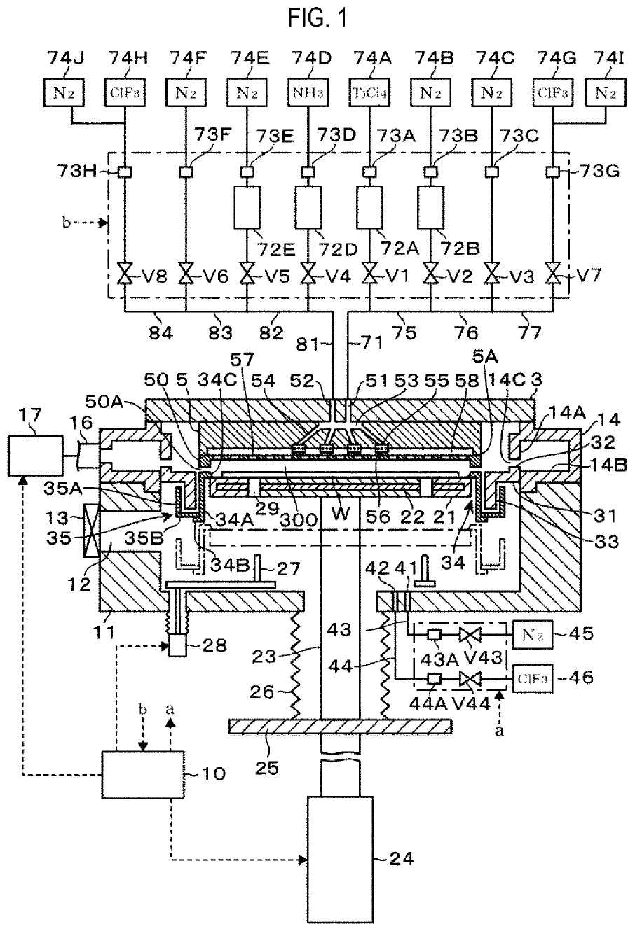

A film forming apparatus according to an embodiment of the present disclosure will be described with reference to the longitudinal sectional side view of FIG. 1. The film forming apparatus includes a flat circular process container 11. The process container 11 is a process chamber in which a vacuum atmosphere is formed and a wafer W as a circular substrate having a diameter of, for example, 300 mm is stored. The film forming apparatus forms a TiN (titanium nitride) film through atomic layer deposition (ALD) by alternately and repeatedly supplying a TiCl₄ (titanium tetrachloride) gas as a source gas and a NH₃ (ammonia) gas as a reaction gas to the wafer W. Between a time period for supplying the TiCl₄ gas and a time period for supplying the NH₃ gas, a N₂ (nitrogen) gas which is an inert gas is supplied as a purge gas to substitute the internal atmosphere of the process container 11 from the TiCl₄ gas atmosphere or the NH₃ gas atmosphere into a N₂ gas atmosphere. During the film forming process through ALD, a N₂ gas is continuously supplied to the process container 11 as a carrier gas for introducing the TiCl₄ gas and the NH₃ gas to the process container 11. After a completion of the film forming process of a plurality of wafers W, a cleaning gas (ClF₃ gas) is supplied to the process container 11 and a cleaning process is performed to remove the TiN film adhering to each part in the process container 11.

A loading and unloading port 12 for the wafer W and a gate valve 13 for opening and closing the loading and unloading port 12 are provided in the side wall of the process container 11. An exhaust duct 14, which forms a part of the process container 11 and is formed by curving a duct having a rectangular transversal section into an annular shape, is provided above the loading and unloading port 12. The inner lower corner of the annular exhaust duct 14 is notched such that the inside and the outside of the exhaust duct 14 communicate with each other through the notch. In the exhaust duct 14, a vertical wall above the notch is denoted by reference numeral 14A and a bottom wall disposed radially outward from the notch is denoted by reference numeral 14B.

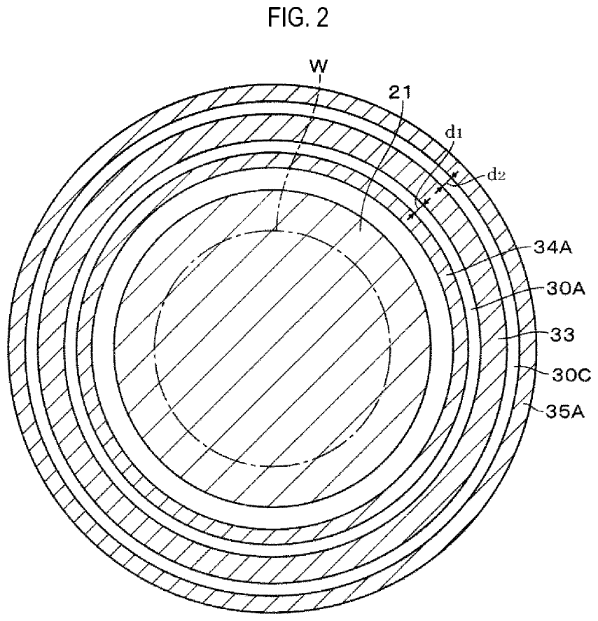

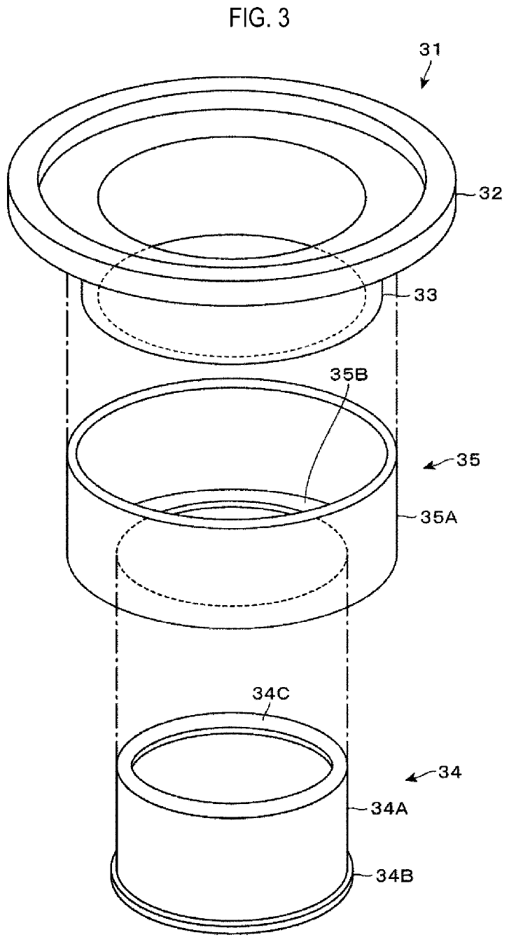

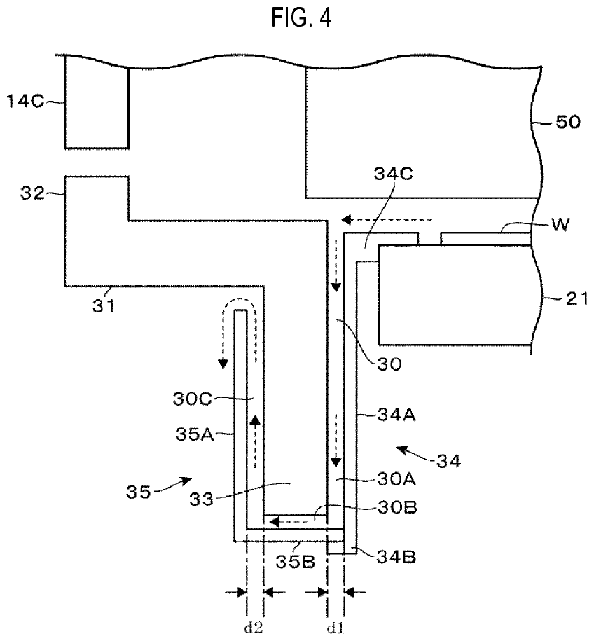

An outer peripheral end of a wide horizontal annular plate 31, which is a first annular body and formed of aluminum, is connected to the inner peripheral end of the bottom wall 14B of the exhaust duct 14. The annular plate 31 is supported by the exhaust duct 14. The configuration of the annular plate 31 will be described with reference to FIG. 2 which is a partial transversal sectional plan view of the film forming apparatus, FIG. 3 which is an exploded perspective view of the annular plate 31, a cylindrical member 34, and a guide member 35 to be described later, and FIG. 4 which is a longitudinal sectional view of the annular plate 31, the cylindrical member 34, and the guide member 35. An outer peripheral edge portion of the annular plate 31 protrudes upward to form a flat annular protrusion 32. The upper end of the annular protrusion 32 faces the lower end of the vertical wall 14A of the exhaust duct 14 through a gap. The gap is configured as an exhaust port 14C for exhausting the interior of the process container 11. As the interior of the exhaust duct 14 is exhausted by an exhaust mechanism 17 to be described later, the interior of the process container 11 is exhausted through the exhaust port 14C. An inner peripheral edge portion of the annular plate 31 protrudes downward to form an annular protrusion 33 which is a second annular body.

Referring back to FIG. 1, the exhaust duct 14 is connected to the exhaust mechanism 17, which is constituted by a pressure regulation valve and a vacuum pump, via an exhaust pipe 16. By adjusting a degree to which the pressure regulation valve is open, based on a control signal output from a controller 10 to be described later, the internal pressure of the process container 11 is set to a desired vacuum pressure.

A circular and horizontal stage 21 is surrounded by the annular plate 31 in a plan view. A heater 22 is embedded in the stage 21 which forms a mounting part. The heater 22 heats the wafer W to, for example, 400 degrees C. to 700 degrees C. An upper end of a support 23, which penetrates the bottom of the process container 11 and extends in the vertical direction, is connected to a central portion in the lower surface of the stage 21, and a lower end of the support 23 is connected to an elevation mechanism 24. The stage 21 is moved upward and downward by the elevation mechanism 24 between a lower position indicated by a chain line in FIG. 1 and an upper position indicated by a solid line in FIG. 1. The lower position is a position at which the wafer W is delivered between the stage 21 and a transfer mechanism of the wafer W entering the process container 11 from the loading and unloading port 12. When the wafer W is positioned at the lower position, the upper surface of the stage 21 is located below the lower end of the annular protrusion 33. The upper position is a position at which the wafer W is processed. When the wafer W is positioned at the upper position, the stage 21 is surrounded by the annular protrusion 33.

In FIG. 1, reference numeral 25 denotes a flange provided in the support 23 below the bottom of the process container 11, and reference numeral 26 denotes an expandable bellows having an upper end connected to the bottom of the process container 11 and a lower end connected to the flange 25 to ensure airtightness of the interior of the process container 11. In FIG. 1, reference numeral 27 denotes three support pins (only two support pins are shown in FIG. 1), and reference numeral 28 denotes an elevation mechanism for moving the support pins upward and downward. When the stage 21 is positioned at the lower position, the support pins 27 move upward and downward through through-holes 29 formed in the stage 21 so as to protrude and retract with respect to the upper surface of the stage 21. Thus, the wafer W is delivered between the stage 21 and the transfer mechanism.

A purge gas supply port 41 and a cleaning gas supply port 42 are opened at the bottom of the process container 11. A purge gas (N₂ gas) discharged from the purge gas supply port 41 is a gas for preventing a film forming gas from entering the lower portion of the stage 21. A purge gas source 45 and a cleaning gas (ClF₃ gas) source 46 are connected to the purge gas supply port 41 and the cleaning gas supply port 42 via gas supply pipes 43 and 44, respectively. In FIG. 1, reference numerals 43A and 44A denote flow rate adjustors, and reference numerals V43 and V44 denote valves.

A ceiling plate 3 is provided above the exhaust duct 14 so as to close the process container 11 from top. In the ceiling plate 3, two gas introduction paths 51 and 52 extending in the vertical direction, a flat space 53 having an upper portion in communication with the lower ends of the gas introduction paths 51 and 52, and a plurality of gas paths 54 extending obliquely downward from different positions in a lower portion of the flat space 53 are formed. A lower central portion of the ceiling plate 3 forms a protrusion 5 protruding downward, and the flat space 53 and gas flow paths 54 are formed in the protrusion 5. The central region in the lower surface of the protrusion 5 forms a horizontal opposing surface facing the front surface of the stage 21. The peripheral edge portion of the opposing surface further protrudes downward to form an annular protrusion 5A, and a circular shower plate 50 having a peripheral edge extending along the annular protrusion 5A is provided so as to face the stage 21. A space surrounded by the shower plate 50, the annular protrusion 5A, and the opposing surface defines a diffusion space 58. The protrusion 5 and the shower plate 50 correspond to a film forming gas supply.

A plurality of gas dispersion parts 55, each of which has a flat circular shape, is installed in the opposing surface. The gas dispersion parts 55 are disposed, for example, along a concentric circle having a center coinciding with the center of the stage 21 in a plan view. The lower ends of the gas flow paths 54 are respectively connected to gas inlets (not shown) provided in upper portions of the gas dispersion parts 55. A plurality of gas discharge holes 56 is opened at intervals in the circumferential direction on the side peripheral surfaces of the gas dispersion portions 55. Thus, a gas introduced from the gas flow paths 54 into the gas dispersion parts 55 is discharged from the gas discharge holes 56 and is diffused through the diffusion space 58 in the lateral direction. The gas diffused in such a manner is discharged from gas discharge holes 57 formed in the shower plate 50 toward the stage 21. Further, an annular protrusion 50A is formed on the lower surface of the shower plate 50 along the peripheral edge portion of the shower plate 50.

Further, as shown in FIGS. 1 to 4, a cylindrical member 34 as a first component is installed around the stage 21 so as to surround the stage 21. The cylindrical member 34 is made of, for example, alumina. The cylindrical member 34 has a cylindrical shape longer than the thickness of the stage 21, and includes a cylindrical portion 34A corresponding to an inner annular body. The cylindrical portion 34A has a flow path defining surface that extends along the inner peripheral surface and the lower end surface of the annular protrusion 33 of the annular plate 31 when the stage 21 is positioned at the upper position. The lower end of the cylindrical portion 34A is bent outward in a radial direction so as to form a support portion 34B that supports a guide member 35 to be described later. A horizontal portion 34C extending inward in the radial direction is formed at the upper end of the cylindrical member 34, and the cylindrical member 34 is fixed to the periphery of the upper surface of the stage 21 by the horizontal portion 34C. The upper surface of the horizontal portion 34C faces the annular protrusion 50A on the lower surface of the shower plate 50. When the stage 21 is positioned at the upper position, a slight gap is formed between the annular protrusion 50A and the upper surface of the horizontal portion 34C.

When the stage 21 is moved to the upper position, a process space 300 of the wafer W surrounded by the upper surface of the stage 21, the lower surface of the shower plate 50, the annular protrusion 50A, and the horizontal portion 34C is defined. Further, as described earlier, when a gas is supplied to the wafer W through the shower plate 50, the supplied gas spreads in the process space 300, is exhausted above the annular plate 31 through the gap between the annular protrusion 50A and the horizontal portion 34C, and is exhausted through the exhaust duct 14. The outer peripheral surface of the cylindrical member 34 corresponds to a first peripheral surface.

The guide member 35, which is a second component and has a substantially cylindrical shape, surrounds the periphery of the cylindrical member 34. The guide member 35 is made of, for example, alumina, and has a cylindrical portion 35A that corresponds to a vertically-extending upper annular body having a second peripheral surface on the inner peripheral surface of the guide member 35. A horizontal portion 35B corresponding to a lower annular body extends inward from the lower end of the cylindrical portion 35A. The horizontal portion 35B is disposed and fixed on the upper surface of a support portion 34B of the cylindrical member 34. When the stage 21 moves upward and downward, the cylindrical member 34 and the guide member 35 move upward and downward integrally with the stage 21. The cylindrical member 34 and the guide member 35 correspond to a third annular body.

When the stage 21 is raised to the upper position as shown in FIG. 4, the annular protrusion 33 at the inner edge portion of the annular plate 31 is inserted between the outer peripheral surface of the cylindrical portion 34A and the inner peripheral surface of the cylindrical portion 35A of the guide member 35. At this time, as shown in FIGS. 2 and 4, a very narrow annular gap 30A is formed between the outer peripheral surface of the cylindrical portion 34A and the inner peripheral surface of the annular protrusion 33, and a very narrow annular gap 30C is formed between the outer peripheral surface of the annular protrusion 33 and the inner peripheral surface of the cylindrical portion 35A of the guide member 35. Further, a very narrow annular gap 30B is formed between the lower end surface of the annular protrusion 33 and the upper surface of the horizontal portion 35B of the guide member 35.

The widths of the gaps 30A to 30C are set such that the cylindrical member 34, the annular plate 31, and the guide member 35 do not interfere with one another even when thermal expansion or thermal contraction occurs in the cylindrical member 34, the annular plate 31, and the guide member 35 by raising the temperature of the stage 21 from room temperature to 700 degrees C.

In the above-described configuration, when the stage 21 is positioned at the upper position and a gas is supplied to the upper surface of the stage 21, a bent flow path 30 is formed as shown in FIG. 4, in which the gas entering the gap 30A flows downward through the gap 30A, flows outward in the radial direction through the gap 30B, and flows upward through the gasp 30C in this order. Therefore, the gas entering the gap 30A is guided by the bent flow path 30 and flows to a space outside the guide member 35 and below the annular plate 31. Further, as shown in FIG. 1, when the stage 21 is moved downward to the lower position, a gap is formed between the lower end of the cylindrical member 34 and the lower surface of the guide member 35 and the bottom surface of the process container 11.

As shown in FIG. 1, the downstream ends of pipes 71 and 81 are respectively connected to the upstream ends of the gas introduction paths 51 and 52 formed in the ceiling plate 3. The upstream end of the pipe 71 is connected to a gas source 74A of TiCl₄ gas as a processing gas via a valve V1, a gas storage tank 72A, and a flow rate adjustor 73A in this order. The flow rate adjustor 73A is configured by a mass flow controller, and adjusts a flow rate of the TiCl₄ gas supplied downward from the gas source 74A. Other flow rate adjustors 73B to 73F to be described later are also configured in the same manner as the flow rate adjustor 73A, each of which adjusts a flow rate of a gas supplied to the downstream side of pipes.

The gas storage tank 72A as a gas storage temporarily stores the TiCl₄ gas supplied from the gas source 74A before supplying the TiCl₄ gas to the process container 11. After the TiCl₄ gas is stored and the internal pressure of the gas storage tank 72A is increased to a predetermined pressure, the TiCl₄ gas is supplied from the gas storage tank 72A to the gas introduction path 51. Supply and stop of the TiCl₄ gas from the gas storage tank 72A to the gas introduction path 51 is performed by opening and closing the valve V1. By temporarily storing the TiCl₄ gas in the gas storage tank 72A in this manner, the TiCl₄ gas can be supplied to the process container 11 at a relatively high flow rate. As with the gas storage tank 72A, gases supplied from gas sources at the upstream side of the pipes are temporarily stored in gas storage tanks 72B, 72D, and 72E forming gas storages to be described later. Supply and stop of the gases from the gas storage tanks 72B, 72D, and 72E to the gas introduction paths 51 and 52 is performed by opening and closing valves V2, V4, and V5 installed at the downstream side of the gas storage tanks 72B, 72D, and 72E, respectively.

The downstream end of a pipe 75 is connected to the pipe 71 at the downstream side of the valve V1. The upstream end of the pipe 75 is connected to a N₂ gas source 74B via the valve V2, the gas storage tank 72B, and the flow rate adjustor 73B in this order. Further, the downstream end of a pipe 76 is connected to the pipe 75 at the downstream side of the valve V2. The upstream end of the pipe 76 is connected to a N₂ gas source 74C via a valve V3 and a flow rate adjustor 73C in this order.

Further, the downstream end of a pipe 77 is connected to the pipe 76 at the downstream side of the valve V3. The upstream end of the pipe 77 is branched into two pipes via a valve V7 and a flow rate adjustor 73G in this order, and a cleaning gas (ClF₃) source 74G and a N₂ gas source 741 are respectively connected to the ends of the two pipes. The cleaning gas source 74G and the N₂ gas source 741 are configured to turn on and turn off the gas supply independently. Thus, it is possible to supply three gas types, i.e., the cleaning gas only, the N₂ gas only, and both of the cleaning gas and the N₂ gas, to the pipe 77.

Next, the pipe 81 will be described. The upstream end of the pipe 81 is connected to a NH₃ gas source 74D via the valve V4, the gas storage tank 72D, and a flow rate adjustor 73D in this order. The downstream end of a pipe 82 is connected to the pipe 81 at the downstream side of the valve V4. The upstream end of the pipe 82 is connected to a N₂ gas source 74E via the valve V5, the gas storage tank 72E, and a flow rate adjustor 73E in this order. Further, the downstream end of a pipe 83 is connected to the pipe 82 at the downstream side of the valve V5. The upstream end of the pipe 83 is connected to a N₂ gas source 74F via a valve V6 and the flow rate adjustor 73F in this order.

Further, the downstream end of a pipe 84 is connected to the pipe 83 at the downstream side of the valve V6. The upstream end of the pipe 84 is branched into two pipes via a valve V8 and a flow rate adjustor 73H in this order, and a cleaning gas source 74H and a N₂ gas source 74J are respectively connected to the ends of the two pipes. The cleaning gas source 74H and the N₂ gas source 74J are configured to turn on and turn off the gas supply independently. Thus, it is possible to supply three gas types, i.e., the cleaning gas only, the N₂ gas only, and both of the cleaning gas and the N₂ gas, to the pipe 84.

The N₂ gas supplied from each of the N₂ gas sources 74B and 74E is supplied to the process container 11 to perform the purge process described above. The N₂ gas supplied from each of the N₂ gas sources 74C and 74F is a carrier gas for the TiCl₄ gas and the NH₃ gas. Since the carrier gas is continuously supplied to the process container 11 during the process of the wafer W as described above, the carrier gas is also supplied to the process container 11 during the purge process. Therefore, a time period during which the carrier gas is supplied to the process container 11 overlaps a time period during which the N₂ gas from each of the gas sources 74B and 74E is supplied in the process container 11 to perform the purge process. Thus, the carrier gas is also used in the purge process. In the present disclosure, for convenience of explanation, a gas supplied from the N₂ gas sources 74B and 74E will be described as a purge gas, and a gas supplied from the N₂ gas sources 74C and 74F will be described as a carrier gas.

The film forming apparatus includes the controller 10. The controller 10 is configured by a computer and includes a program, a memory, and a CPU. The program incorporates a step group so that a series of operations to be described later in the film forming apparatus can be performed. The controller 10 outputs control signals to various parts of the film forming apparatus according to the program. Thus, operations of the various parts are controlled. Specifically, operations such as opening and closing of the valves V1 to V8, V43, and V44, adjustment of gas flow rates by the flow rate adjustors 73A to 73H, 43A, and 44A, adjustment of the internal pressure of the process container 11 by the pressure adjustment mechanism 18, and adjustment of the temperature of the wafer W by the heater 22 are controlled by the control signals. The program is stored in a storage medium such as, for example, a compact disk, a hard disk, or a DVD, and is installed in the controller 10.

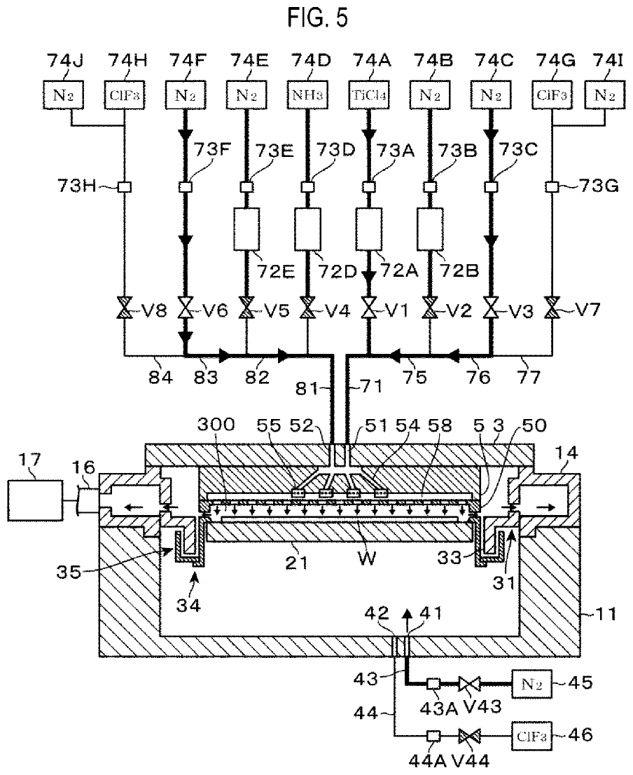

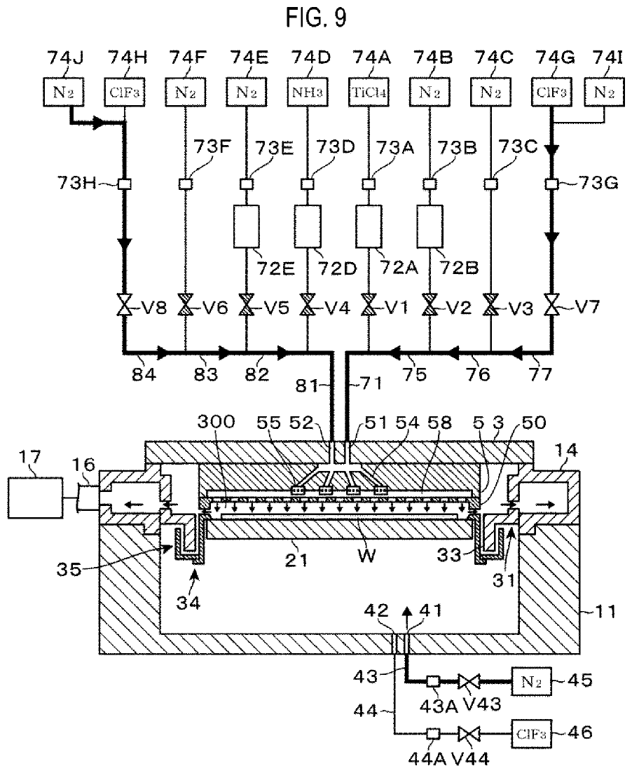

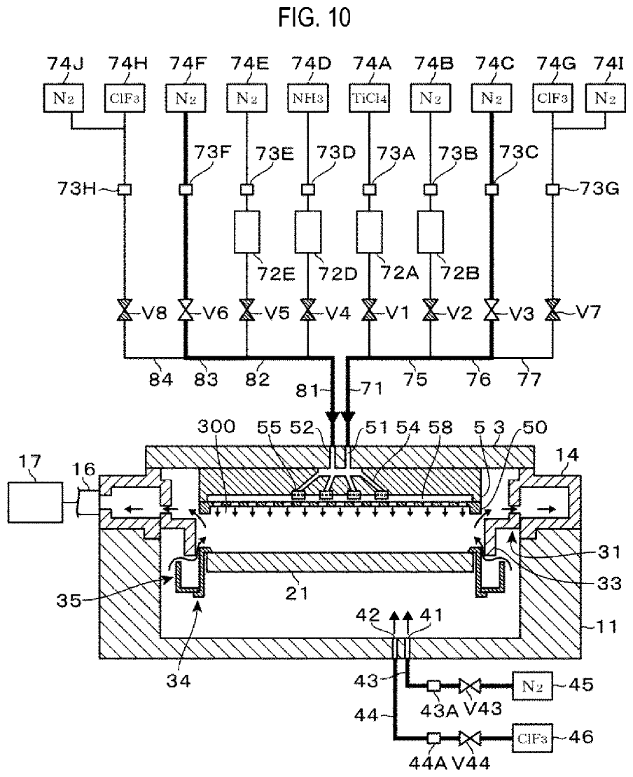

Next, a film forming process in the film forming apparatus will be described with reference to FIGS. 5 to 7 which show an open and close state of each valve and a flow state of a gas in each pipe. In FIGS. 5 to 7 and in FIGS. 9 and 10 for explaining a cleaning process to be described later, a closed valve V is hatched to distinguish from an opened valve V. Further, for the pipes 71, 75 to 77, and 81 to 84, a portion where a gas is flowing toward a downstream side is shown thicker than a portion where a gas is not flowing.

First, in a state where the valves V1 to V8 are closed, the wafer W is transferred into the process container 11 by the transfer mechanism and is mounted on the stage 21 at the delivery position. After the transfer mechanism retracts from the interior of the process container 11, the gate valve 13 is closed. The wafer W is heated to the temperature described above, for example, 450 degrees C. by the heater 22 of the stage 21 and the stage 21 is moved upward to the upper position so that the process space 300 is defined. Further, the valve V43 installed in the gas supply pipe 43 arranged in the bottom portion of the process container 11 is opened and a purge gas is supplied from the purge gas supply port 41 to the process container 11 at a flow rate of 3.0 L/min to 20 L/min, for example, 4.0 L/min, while the interior of the process container 11 is adjusted to a predetermined vacuum pressure by the exhaust mechanism 17 connected to the exhaust duct 14 via the exhaust pipe 16.

Then, the valves V3 and V6 are opened, and a carrier gas (N₂ gas) is supplied from the N₂ gas sources 74C and 74F to the gas introduction paths 51 and 52, respectively. Also, a TiCl₄ gas and an NH₃ gas are supplied from the gas source 74A and the gas source 74D to the pipes 71 and 81, respectively. Since the valves V1 and V4 are closed, the TiCl₄ gas and the NH₃ gas are stored in the gas storage tanks 72A and 72D, respectively, and the internal pressures of the gas storage tanks 72A and 72D are increased. Thereafter, as shown in FIG. 5, the valve V1 is opened, and the TiCl₄ gas stored in the gas storage tank 72A is supplied to the process space 300 via the shower plate 50 and is supplied to the wafer W.

In parallel with the supply of the TiCl₄ gas to the wafer W in the process container 11, a purge gas (N₂ gas) is supplied from the gas sources 74B and 74E to the pipes 75 and 82, respectively. Since the valves V2 and V5 are closed, the purge gas is stored in the gas storage tanks 72B and 72E and the internal pressures of the gas storage tanks 72B and 72E are increased.

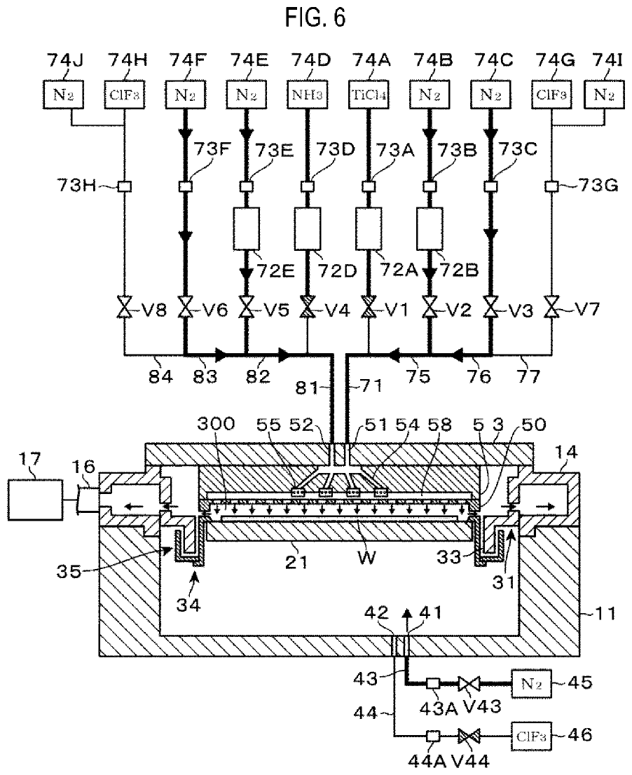

Thereafter, as shown in FIG. 6, the valve V1 is closed and the valves V2 and V5 are opened. As a result, the supply of TiCl₄ gas to the process container 11 is stopped, and the purge gas stored in the gas storage tanks 72B and 72E is supplied to the gas introduction paths 51 and 52. Similarly to the TiCl₄ gas, the purge gas spreads through the diffusion space 58 and is discharged from the shower plate 50 to the process space 300. Then, the purge gas is diffused through the process space 300 in the lateral direction, and is purged to the exhaust duct 14. As a result, the TiCl₄ gas remaining in the process space 300 is removed from the process container 11.

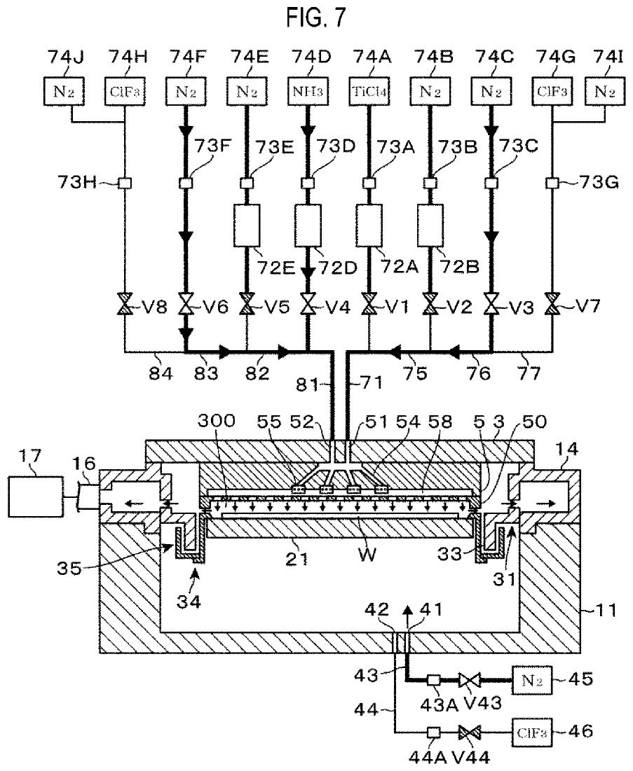

Subsequently, as shown in FIG. 7, the valves V2 and V5 are closed and the valve V4 is opened. As a result, the supply of purge gas to the gas introduction paths 51 and 52 is stopped, and the NH₃ gas stored in the gas storage tank 72D is supplied to the gas introduction path 52 and is discharged from the shower plate 50 to the process space 300. Similar to the TiCl₄ gas and the purge gas, the NH₃ gas is supplied from the shower plate 50 to the process space 300, and is supplied to each portion in the surface of the wafer W with high uniformity. As a result, a nitriding reaction of the TiCl₄ gas adsorbed with high uniformity to the surface of the wafer W proceeds to form a thin layer of TiN as a reaction product. Also, since the valves V2 and V5 are closed, the purge gas supplied from the gas sources 74B and 74E to the pipes 75 and 82 is stored in the gas storage tanks 72B and 72E and the internal pressures of the gas storage tanks 72B and 72E are increased.

Thereafter, the valve V4 is closed and the valves V2 and V5 are opened. Thus, the supply of NH₃ gas to the process container 11 is stopped, and the purge gas stored in the gas storage tanks 72B and 72E is introduced to the gas introduction path 51 and 52 and is discharged from the shower plate 50 to the process space 300 as shown in FIG. 6. As a result, the unreacted NH₃ gas remaining in the process space 300 is removed simultaneously or substantially simultaneously from above each portion in the surface of the wafer W to stop the nitriding reaction, which makes the thickness of the TiN thin layer even in each portion in the surface of the wafer W. The NH₃ gas is purged to the exhaust duct 14 and is removed from the process container 11. Since the valve V4 is closed during the purge process, the NH₃ gas supplied from the gas source 74D to the pipe 81 is stored in the gas storage tank 72D and the internal pressure of the gas storage tank 72D is increased.

Assuming that the cycle including supplying the TiCl₄ gas, the purge gas, the NH₃ gas, and the purge gas to wafer W in this order is one cycle, the cycle is repeatedly performed such that thin TiN layers are deposited on the surface of wafer W, thereby forming a TiN film. When a predetermined number of cycles are executed, the wafer W is unloaded from the process container 11 in a reverse order to that at the time of loading the wafer W to the process container 11.

As described above, the film forming process is performed by supplying a gas to the wafer W. However, in some cases of using conventional film forming apparatuses, a film forming gas such as a TiCl₄ gas enters a gap between the annular protrusion 33 of the annular plate 31 and the stage 21 and flows to a space below the stage 21. In this case, a reaction product adheres to the bottom surface of the stage 21, and emissivity of heat at a location in the stage 21 where the reaction product adheres changes. As a result, since in-plane uniformity of a heating temperature of the wafer W when the wafer W is heated may deteriorate, in-plane uniformity of a film thickness of the wafer W may deteriorate. Thus, by supplying a purge gas from the purge gas supply port 41 formed at the lower portion of the stage 21 in the film forming apparatus, the wraparound of the film forming gas to the space below the stage 21 is suppressed.

A method of enhancing productivity by supplying the gases stored in the gas storage tanks 72A, 72B, 72D, and 72E at once to the narrow process space 300 has been used in recent years. In this method, since a gas pressure above the stage 21 is easily increased, a film forming gas which was going to flow from the process space 300 to the exhaust duct 14 easily enters a gap between the stage 21 and the annular plate 31.

The inflow of the film forming gas to the space below the stage 21 may be suppressed by increasing the flow rate of the purge gas toward the space below the stage 21. However, when the flow rate of a gas in the process space 300 is small, the purge gas easily flows to the process space 300. When the purge gas flows to the process space 300, a gas flow of the film forming gas may be disturbed by the purge gas or the purge gas may be discharged to the wafer W, which may cause deterioration in film thickness uniformity or film quality.

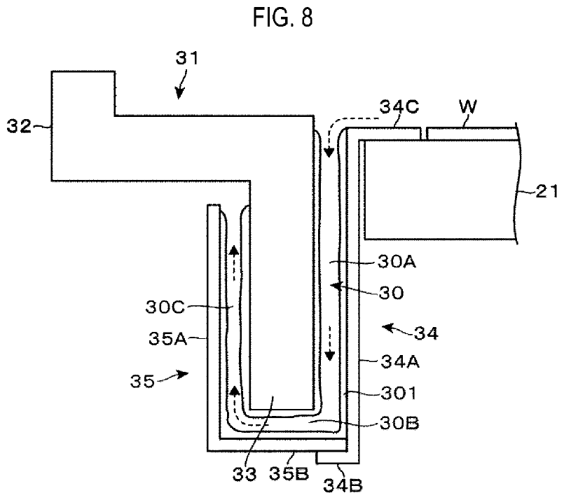

In the present embodiment, the guide member 35 is provided at the side of the outer periphery of the cylindrical member 34 provided around the stage 21. Thus, when the stage 21 is positioned at the upper position, the bent flow path 30 which is a connection of the gap 30A between the outer peripheral surface of the cylindrical member 34 and the inner peripheral surface of the annular protrusion 33 of the annular plate 31, the gap 30C between the upper surface of the horizontal portion 35B of the guide member 35 and the lower end surface of the annular protrusion 33, and the gap 30B between the inner peripheral surface of the vertical portion of the guide member 35 and the outer peripheral surface of the annular protrusion 33, is formed. Therefore, as shown in FIG. 8, a gas which has entered between the stage 21 and the annular plate 31 is guided to flow in the bent flow path 30 and is discharged to a space below the annular plate 31.

As such, by forming the bent flow path 30 in the gap between the stage 21 and the annular plate 31 and increasing the length of the flow path, Peclet number of a gas passing through the space below the stage 21 can be increased as shown in an example to be described later. Thus, it is possible to prevent the film forming gas from flowing into the space below the stage 21 from above.

When the gases exhausted from the process space 300 enter the bent flow path 30, a film forming gas (for example, a TiCl₄ gas), which is likely to generate the reaction product 301, in the gases flowing through the bent flow path 30 adheres to the annular protrusion 33, the cylindrical member 34, and the guide member 35 and is removed.

By forming the bent flow path 30 to increase the length of the flow path of the gases which flow into the bent flow path 30 from the process space 300 and are discharged to the space below the annular plate 31, the film forming gas is trapped and less likely to flow into the space below the stage 21, so that the content of the film forming gas in the gases is reduced. Accordingly, adhesion of the film forming gas to the lower surface of the stage 21 is suppressed.

When the film forming process of the wafer W is repeated, reaction products resulting from the film forming gas are accumulated on the inner wall of the process container 11 or the surfaces of the cylindrical member 34, the guide member 35, and the annular plate 31, which causes generation of particles. Therefore, during the process of the wafer W in the film forming apparatus, a cleaning process of the interior of the process container 11 is performed every predetermined time or every completion of processing a predetermined number of wafers W.

The cleaning process will be described. For example, after the processed wafer W is discharged from the process container 11, the stage 21 on which no wafer is mounted is positioned at the upper position. Further, with the valves V1 to V6 closed, the interior of the process container 11 is vacuum-exhausted and the internal pressure of the process container 11 is adjusted.

Next, as shown in FIG. 9, while adjusting the internal pressure of the process container 11, the temperature of the stage 21 is adjusted by the heater 22 to a temperature at the time of the cleaning process, for example, 160 to 250 degrees C. Further, the valve V7 is opened to supply a cleaning gas to the gas introduction path 51. At this time, the valve V8 is opened to supply a purge gas to the gas introduction path 52. As a result, a nitrogen gas and the cleaning gas are supplied from the shower plate 50 to the process space 300. Similarly, with the stage 21 positioned at the upper position, a nitrogen gas is supplied to the gas introduction path 51 and a cleaning gas is supplied to the gas introduction path 52 (not shown). In this manner, by supplying the cleaning gas to the gas introduction paths 51 and 52 in turn, the reaction product 301 adhering to the interiors of the gas introduction paths 51 and 52 can be removed. At this time, the cleaning gas is exhausted from the process space 300 to the exhaust duct 14 via a space above the annular plate 31.

Further, with the stage 21 positioned at the upper position, the valve V43 is closed and the valve V44 is opened. Accordingly, a cleaning gas is supplied from the gas supply port 44 on the bottom surface of the process container 11 to the space below the stage 21 (not shown). Thus, the cleaning gas fills the space below the stage 21 and the reaction product 301 adhering to the space below the stage 21 is removed.

Subsequently, the supply of the cleaning gas is stopped, and the stage 21 is moved downward to the lower position. As a result, the cleaning gas filled in the space below the stage 21 wraps around into the space above the stage 21 from the gap between the stage 21 and the annular plate 31, and is exhausted through the exhaust duct 14.

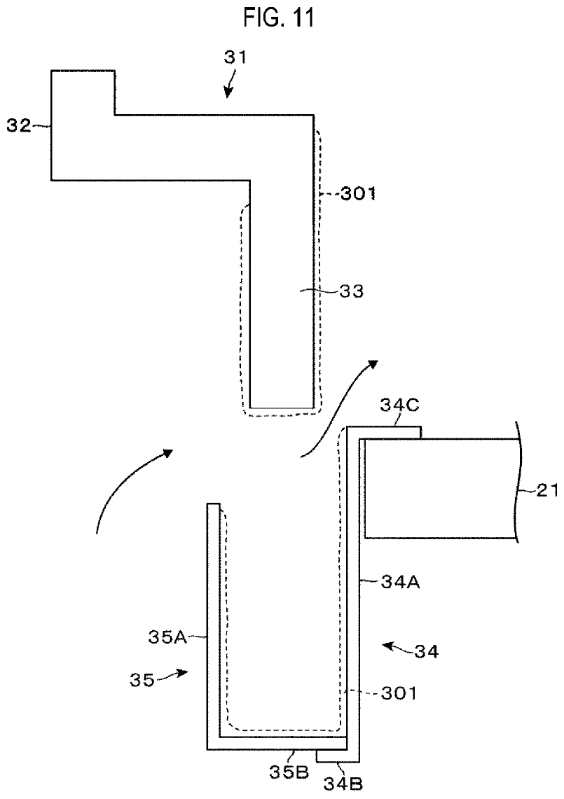

Further, with the stage 21 positioned at the lower position, the cleaning gas is sequentially supplied from the gas introduction path 51, the gas introduction path 52, and the gas supply port 44 on the bottom surface of the process container 11. FIG. 10 shows an example in which the cleaning gas is supplied from the gas supply port 44 on the bottom surface of the process container 11. In this manner, in each of the states where the stage 21 is positioned at the upper position and at the lower position, the cleaning gas is sequentially supplied from the gas introduction path 51, the gas introduction path 52, and the gas supply port 44 on the bottom surface of the process container 11. As a result, the reaction product 301 adhering to the interior of the process container 11 is removed and exhausted through the exhaust duct 14. Further, as described above with reference to FIG. 8, the reaction product 301 generated by the film forming gas flowing from the process space 300 to the bent flow path 30 during the film forming process of the wafer W adheres to the annular protrusion 33, the cylindrical member 34, and the guide member 35. At this time, as shown in FIG. 10, by supplying the cleaning gas to the process container 11 with the stage 21 positioned at the lower position, the cleaning gas supplied to the process container 11 spreads over the inner and outer peripheral surfaces of the annular protrusion 33 of the annular plate 31, the inner peripheral surface of the guide member 35, and the outer peripheral surface of the cylindrical member 34. As a result, as shown in FIG. 11, the reaction product 301 adhered to the annular plate 31, the guide member 35, and the cylindrical member 34 is removed.

According to the above-described embodiment, the film forming apparatus for forming a film by supplying a film forming gas to the wafer W, which is mounted on the stage 21 in the process container 11, from the shower plate 50 facing the stage 21 includes the annular plate 31 surrounding the periphery of the stage 21 with a gap interposed between the annular plate 31 and the stage 21, and the annular protrusion 33 extending downward from the inner peripheral edge of the annular plate 31. The film forming apparatus further includes the cylindrical member 34 having the cylindrical portion 34A, which extends from the peripheral edge of the stage 21 and has the flow path defining surface extending along the inner peripheral surface and the lower end surface of the annular protrusion 33 when the stage 21 is positioned at the upper position. The film forming apparatus further includes the guide member 35 extending horizontally from the lower end of the cylindrical member 34 and extending upward along the outer peripheral surface of the annular protrusion 33. The bent flow path 30 is defined between the cylindrical member 34 and the guide member 35 and the annular protrusion 33. As such, the bent flow path 30 is a flow path through which a gas passes from above the stage 21 to below the stage 21. By increasing the length of the flow path, it is possible to reduce diffusion of a gas which flows out of the bent flow path 30 and flows to a space below the annular plate 31 and the stage 21.

Even when the film forming gas enters the gap between the stage 21 and the annular protrusion 33, the film forming gas can be trapped on the flow path defining surface, the inner peripheral surface of the guide member 35, and the annular protrusion 33. Therefore, it is possible to reduce the film forming gas in the gases flowing out of the bent flow path 30 and flowing to the space below the annular plate 31 and the stage 21. As a result, since the diffusion of the gas below the stage 21 can be suppressed and the content of the film forming gas can be reduced, the adhesion of the film forming gas to the lower surface of the stage 21 can be reduced.

If the cylindrical member 34 and the guide member 35 are integrally formed, there is a concern that a portion corresponding to the guide member 35 is damaged by a stress, which is increased due to thermal expansion or the like caused by an increase in temperature of the stage 21 and is applied to the portion. By forming the cylindrical member 34 and the guide member 35 separately from each other, such a damage can be suppressed, and the manufacturing cost can be reduced as compared with the case where the cylindrical member 34 and the guide member 35 are integrally formed. From the viewpoint of suppressing a stress applied to a joint portion of the cylindrical member 34 and the guide member 35, the cylindrical member 34 and the guide member 35 may be made of the same material, for example, ceramics.

If a portion of the cylindrical member 34 protruding downward than the stage 21 is long, the space below the stage 21 may be partitioned by the lower end portion of the cylindrical member 34. In this case, there is a concern that the purge gas and the cleaning gas supplied from the purge gas supply port 41 and the cleaning gas supply port 42 on the bottom surface of the process container 11 does not evenly spread in the process container 11. Further, there is a problem that an air flow below the stage 21 is hindered. According to the above-described embodiment, since the cylindrical member 34 and the guide member 35 are bent, the bent flow path 30, which is formed by the flow path formed by the cylindrical member 34, the guide member 35, and the annular plate 31, is bent upward and downward. Therefore, it is possible to increase the length of the flow path while suppressing a portion of the cylindrical member 34 protruding downward than the stage 21 from being long. In addition, if the portion of the cylindrical member 34 protruding downward than the stage 21 is long, it is necessary to expand the space below the stage 21 so as not to hinder the air flow below the stage 21. When the space below the stage 21 is expanded, a large exhaust amount is required to maintain the vacuum pressure, or the supply amount of the purge gas or the cleaning gas is increased. In the present embodiment, since the lower end portion of the cylindrical member 34 can be kept short by forming the bent flow path by the cylindrical member 34, the guide member 35, and the annular plate 31, it is possible to prevent the air flow below the stage 21 from being hindered without expanding the space below the stage 21.

Further, since the diffusion of the film forming gas to of the space below the stage 21 can be reduced even when the productivity is improved by increasing the flow rate of the film forming gas, it is not necessary to increase the flow rate of the purge gas supplied to the space below the stage 21. For example, the flow rate of the purge gas may be set to about 3.0 L/min to 20 L/min In this manner, since the flow rate of the purge gas supplied to the space below the stage 21 can be reduced, it is possible to suppress the purge gas from entering the process space 300 and achieve stable film formation.

It is preferable to more reliably avoid the interference between the annular protrusion 33 and the cylindrical member 34 and the guide member 35 when the stage 21 is moved upward to the upper position. Therefore, in a state where the stage 21 is heated to the film forming temperature of the wafer W, for example, 450 degrees C., the width d1 of the gap 30A between the outer peripheral surface of the cylindrical member 34 and the inner peripheral surface of the annular protrusion 33 and the width d2 of the gap 30C between the outer peripheral surface of the annular protrusion 33 and the inner peripheral surface of the guide member 35 may be set, in some embodiments, to be 1.0 mm to 5.0 mm in the longitudinal sectional view. Further, in some embodiments, the widths d1 and d2 may be set to be the same to each other. The gap 30B between the upper surface of the horizontal portion 35B of the guide member 35 and the lower end surface of the annular protrusion 33 may have the same width as those of the gaps 30A and 30C.

In some embodiments, the gaps 30A to 30C may be set such that the annular protrusion 33 is prevented from being brought into contact with the cylindrical member 34 and the guide member 35 when the temperature of the stage 21 is changed in a range of room temperature (25 degrees C.) to 700 degrees C.

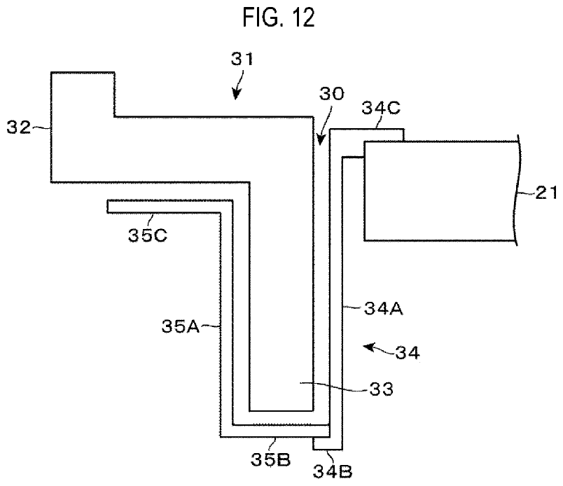

The configuration of the bent flow path 30 is not limited to the above-described embodiment. For example, as shown in FIG. 12, the guide member 35 may have a horizontal portion 35C extending outward from the upper end of the cylindrical portion 35A of the guide member 35 in the radial direction along the lower surface of the annular plate 31.

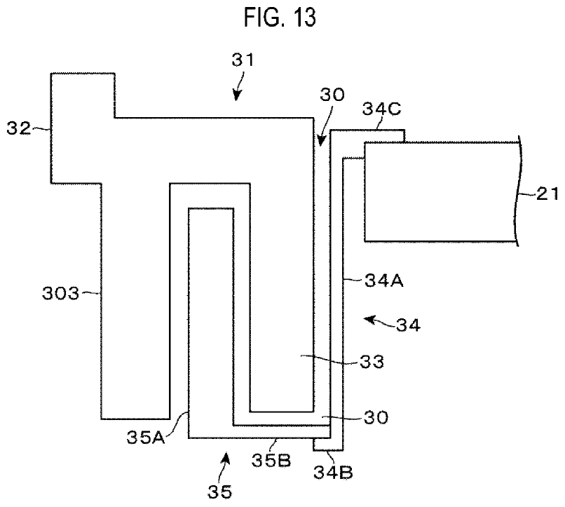

Further, as shown in FIG. 13, the annular plate 31 may have an annular wall portion 303 which protrudes downward from the lower surface of the annular plate 31 and extends along the outer peripheral surface of the guide member 35. With this configuration, the length of the bent flow path 30 can be further increased, and the contact area of the film forming gas flowing through the bent flow path 30 with the annular plate 31, the guide member 35, and the cylindrical member 34 can be further increased. It is considered that Peclet number of the gas passing through the bent flow path 30 is further increased with the increase of the length of the flow path. Thus, the diffusion of the film forming gas to the space below the stage 21 can be further suppressed.

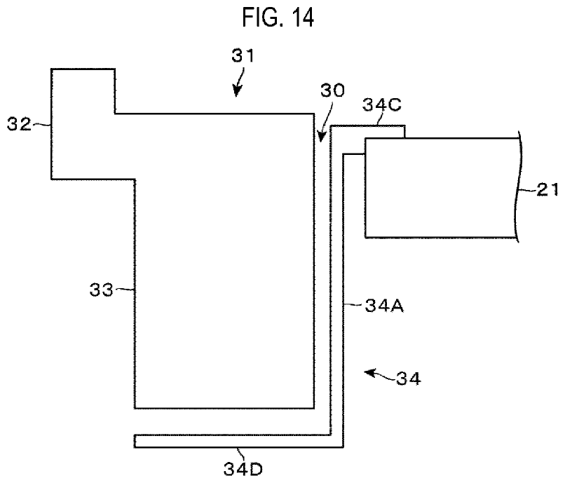

Further, as shown in FIG. 14, the length of the bent flow path 30 may be secured by making the annular protrusion 33 of the annular plate 31 thicker and extending a bent portion 34D horizontally from the lower end of the cylindrical member 34 along the end surface of the lower end portion of the annular protrusion 33.

Even with such a configuration, since the length of the bent flow path 30 can be increased by increasing a length of a flow path between the upper surface of the bent portion 34D and the lower end surface of the annular protrusion 33, the same effects can be achieved.

### EXAMPLES

The following tests were performed to verify the effects of the film forming apparatus according to the present disclosure. The film forming apparatus shown in FIG. 1 was used as an example of the film forming apparatus. Further, as a comparative example, a film forming apparatus having the same configuration as the example except that the guide member 35 is not provided, the support portion 34B is not formed in the cylindrical member 34, and a flow path of a gap is not the bent flow path 30 but a linear flow path shorter than the bent flow path 30 was used. For each of the example and the comparative example, the film forming process according to the method described in the embodiment was sequentially performed on 1,000 sheets of wafers W, and a film thickness distribution of a film formed on each processed wafer W was measured. For each wafer W, a difference (range) between the thinnest portion and the thickest portion of the formed film and the average film thickness were measured.

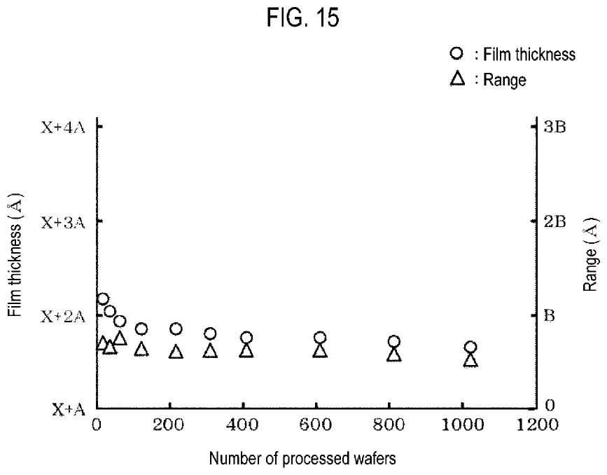

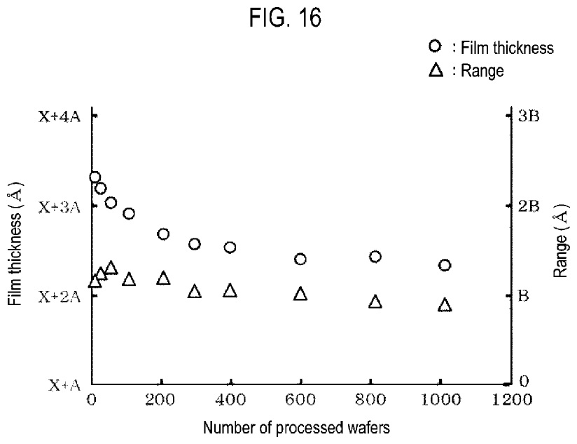

FIGS. 15 and 16 are characteristic diagrams showing an average film thickness (Å) of a film formed on the n^{th} wafer W and a range (Å) between the maximum value and the minimum value of the thickness of the film formed on the n^{th} wafer W (where n is the number of processed wafers), when the film forming process is performed on the first to the 1,000^{th} wafer W using the film forming apparatuses according to the example and the comparative example, respectively.

As shown in FIGS. 15 and 16, in the comparative example, the average film thickness of the film formed on the wafer W is significantly reduced as the number of processed wafers W increases. However, in the example, the decrease in the average film thickness of the film formed on the wafer W is smaller than that in the comparative example even when the number of processed wafers W increases, which means that an error in film thickness between the surfaces of the wafers W is small. The reason is presumed as the following. The average film thickness of the wafer W gradually decreases as a reaction product of the film forming gas adhering to the lower surface of the stage 21 is gradually accumulated. However, in the example, since the outflow of the film forming gas to the space below the stage 21 is suppressed, adhesion of the reaction product of the film forming gas on the lower surface of the stage 21 can be suppressed.

In each of the film forming apparatuses of the example and the comparative example, Peclet number of a gas (measured at the lower end of the flow path) flowing to the space below the stage 21 from the gap between the stage 21 and the annular plate 31 was calculated, and based on the calculated Peclet number, a necessary amount of a flow rate of a purge gas, which is supplied from below the stage 21, for preventing back diffusion of the gas was calculated. The calculated flow rate of the purge gas was 6.6 L in the comparative example, while 4 L or so in the example. According to this results, it can be considered that in the example, the gas is less likely to diffuse to the space below the stage 21 than in the comparative example, and the flow rate of the purge gas supplied from below the stage 21 can be reduced. The reason is presumed that the length of the flow path is increased by configuring the bent flow path 30 in combination of the cylindrical member 34 and the guide member 35.

According to the present disclosure, when a film is formed by supplying a film forming gas to a substrate mounted on a stage, it is possible to prevent the film forming gas from wrapping around into a space below the stage and adhering to the stage.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming apparatus comprising:
a vacuum container defining a process chamber kept in a vacuum atmosphere;
a stage having an upper surface on which a substrate is mounted and a lower surface supported in the process chamber by a support, a central portion of the lower surface being supported by the support, a peripheral portion of the lower surface being spaced apart from a bottom portion of the vacuum container;
a film forming gas supply installed above the stage to face the stage, and configured to supply a film forming gas to the substrate;
an exhaust port opened in a side wall of the vacuum container along an outer periphery of the stage;
a first annular body protruding toward the stage from the side wall of the vacuum container at a location below the exhaust port, an inner peripheral portion of the first annular body facing a circumferential surface of the stage with a gap interposed between the inner peripheral portion and the circumferential surface, the first annular body vertically partitioning the process chamber;
a second annular body extending downward from the inner peripheral portion of the first annular body such that a lower end portion of the second annular body is positioned lower than the peripheral portion of the stage; and
a third annular body extending from the peripheral portion of the stage, such that the third annular body has a flow path defining surface extending along an inner peripheral surface of the second annular body and a lower end surface of the second annular body and a bent flow path, in which the film forming gas leaking into the gap is trapped and forms a film on the flow path defining surface and the second annular body, is formed between the second annular body and the third annular body.

2. The film forming apparatus of claim 1, wherein the flow path defining surface extends along the inner peripheral surface of the second annular body, the lower end surface of the second annular body, and an outer peripheral surface of the second annular body, and wherein the bent flow path is a flow path bent upward and downward.

3. The film forming apparatus of claim 2,
wherein the third annular body includes:
a first component that forms a portion of the flow path defining surface and has a first peripheral surface along the inner peripheral surface of the second annular body, the first component being supported by the stage; and
a second component that forms another portion of the flow path defining surface and has a second peripheral surface along the outer peripheral surface of the second annular body, the second component being supported by the first component, and wherein the first component and the second component are separately formed.

4. The film forming apparatus of claim 3,
wherein the second component includes:
an upper annular body surrounding the outer peripheral surface of the second annular body, an inner peripheral surface of the upper annular body forming the second peripheral surface; and
a lower annular body extending inward from the inner peripheral surface of the upper annular body, an upper surface of the lower annular body facing the lower end surface of the second annular body, and wherein the first component includes:
an inner annular body having an outer peripheral surface that forms the first peripheral surface; and
a support that extends outward from the outer peripheral surface of the inner annular body and supports the lower annular body from below.

5. The film forming apparatus of claim 3, wherein the first component and the second component are made of ceramics.

6. The film forming apparatus of claim 1, wherein the bent flow path includes a portion having a width of 1.0 mm to 5.0 mm in a longitudinal sectional view.

7. The film forming apparatus of claim 1,
wherein the film forming gas supply alternately and repeatedly supplies a source gas as the film forming gas and a reaction gas reacting with the source gas to form a reaction product, and supplies a first purge gas in a period between a period in which the source gas is supplied and a period in which the reaction gas is supplied,
wherein a purge gas supply port for supplying a second purge gas that suppresses the film forming gas from adhering to the lower surface of the stage is formed at the bottom portion of the vacuum container, and
wherein the second purge gas is supplied from the purge gas supply port at 3.0 L/min to 20 L/min while the source gas, the reaction gas, and the first purge gas are being discharged from the film forming gas supply.

8. A film forming method using a film forming apparatus that supplies a film forming gas to a substrate, the method comprising:
forming a vacuum atmosphere in a process chamber of a vacuum container;
mounting a substrate on an upper surface of a stage, a central portion of a lower surface of the stage being supported in the process chamber by a support, a peripheral portion of the lower surface of the stage being spaced apart from a bottom portion of the vacuum container;
forming a film by supplying a film forming gas to the substrate from a film forming gas supply installed above the stage to face the stage; and
exhausting from an exhaust port opened in a side wall of the vacuum container along an outer periphery of the stage,
wherein the film forming apparatus includes:
a first annular body protruding toward the stage from the side wall of the vacuum container at a location below the exhaust port, an inner peripheral portion of the first annular body facing a circumferential surface of the stage with a gap interposed between the inner peripheral portion and the circumferential surface, and the first annular body vertically partitioning the process chamber;
a second annular body extending downward from the inner peripheral portion of the first annular body such that a lower end portion of the second annular body is positioned lower than the peripheral portion of the stage; and
a third annular body extending from the peripheral portion of the stage, such that the third annular body has a flow path defining surface extending along an inner peripheral surface of the second annular body and a lower end surface of the second annular body, and wherein the method further comprises:
trapping the film forming gas leaking into the gap in a bent flow path, which is formed between the second annular body and the third annular body, and forming the film on the flow path defining surface and the second annular body.
